(19) United States
(12) Patent Application Publication
(10) Pub. No.: US 2010/0229795 A1
(43) Pub. Date: Sep. 16, 2010

(54) SUBSTRATE PROCESSING APPARATUS

(75) Inventors: Junichi TANABE, Toyama-shi (JP); Atsushi MORIYA, Toyama-shi (JP); Kiyohisa ISHIBASHI, Toyama-shi (JP)

Correspondence Address: BRUNDIDGE & STANGER, P.C., 2318 MILL ROAD, SUITE 1020, ALEXANDRIA, VA, 22314, US

(73) Assignee: HITACH-KOKUSAI ELECTRIC INC., Tokyo (JP)

(21) Appl. No.: 12/716,855

(22) Filed: Mar. 3, 2010

(30) Foreign Application Priority Data
Mar. 10, 2009 (JP) 2009-055913
Jan. 7, 2010 (JP) 2010-001898

(51) Int. Cl. C23C 16/00

(52) U.S. Cl. 118/725

(57) ABSTRACT

Provided is a substrate processing apparatus that can suppress formation of an Si thin film on the inner wall of a film-forming gas supply nozzle. The substrate processing apparatus comprises a process chamber configured to process a substrate, a heating member configured to heat the substrate, a coating gas supply member including a coating gas supply nozzle configured to supply coating gas into the process chamber, a film-forming gas supply member including a film-forming gas supply nozzle supplying film-forming gas into the process chamber, and a control unit configured to control the heating member, the coating gas supply member, and the film-forming gas supply member. The control unit executes a control such that the coating gas supply nozzle supplies the coating gas to coat a quartz member in the process chamber and the film-forming gas supply nozzle supplies the film-forming gas to form an epitaxial film on the substrate.

### CROSS-REFERENCE TO RELATED PATENT APPLICATION

This U.S. non-provisional patent application claims priority under 35 U.S.C. §119 of Japanese Patent Application Nos. 2009-055913, filed on Mar. 10, 2009, and 2010-001898, filed on Jan. 7, 2010, in the Japanese Patent Office, the entire contents of which are hereby incorporated by reference.

### BACKGROUND OF THE INVENTION

1. Field of the Invention

The present invention relates to a substrate processing apparatus configured to process a substrate.

2. Description of the Prior Art

As one of manufacturing processes of a semiconductor device such as a dynamic random access memory (DRAM), a substrate processing process has been performed, which includes an operation of holding a plurality of substrates in a state where the substrates are spaced a predetermined distance from each other in a stacked shape, to load the substrates into a process chamber, an operation of supplying film-forming gas by a film-forming gas supply nozzle installed in the process chamber, to form thin films on the substrates, and an operation of unloading the substrates from the inside of the process chamber. Such a substrate processing process has been performed by using a substrate processing apparatus, which includes a process chamber configured to process a substrate, a heating member configured to heat a substrate, and a film-forming gas supplying member having a film-forming gas supply nozzle configured to supply film-forming gas into the process chamber.

In the above-described substrate processing process, to suppress the contamination of a substrate due to a quartz member installed in the process chamber is suppressed, or to improve heat conduction efficiency in the process chamber, before an operation of forming a thin film on a substrate, a process of coating the quartz member with an silicon (Si) thin film in the process chamber may be performed. In the relevant operation, the inside of the process chamber is heated, coating gas containing silicon (Si) is supplied by a film-forming gas supply nozzle, and an Si thin film is formed on the surface of the quartz member.

However, when the inside of the process chamber is heated, the inside of the film-forming gas supply nozzle is also heated. Thus, when coating gas containing Si is supplied by the film-forming gas supply nozzle, an Si thin film may be formed on the inner wall of the film-forming gas supply nozzle. In addition, in the relevant state, when film-forming gas is supplied into the film-forming gas supply nozzle, another thin film is formed using the formed Si thin film as a base, and the film-forming gas supply nozzle may be closed or broken. In addition, since film-forming gas is consumed in the film-forming gas supply nozzle, it may be difficult to control the flowrate of film-forming gas to be supplied to a substrate.

### SUMMARY OF THE INVENTION

An object of the present invention is to provide a substrate processing apparatus that can suppress the formation of a silicon (Si) thin film on the inner wall of a film-forming gas supply nozzle.

According to an aspect of the present invention, there is provided a substrate processing apparatus comprising: a process chamber configured to process a substrate; a heating member configured to heat the substrate; a coating gas supply member including a coating gas supply nozzle configured to supply coating gas into the process chamber; a film-forming gas supply member including a film-forming gas supply nozzle configured to supply film-forming gas into the process chamber; and a control unit configured to control the heating member, the coating gas supply member, and the film-forming gas supply member, wherein the control unit executes a control such that the coating gas supply nozzle supplies the coating gas to coat a quartz member in the process chamber and the film-forming gas supply nozzle supplies the film-forming gas to form an epitaxial film on the substrate.

### BRIEF DESCRIPTION OF THE DRAWINGS

FIG. 1 is a plan perspective view illustrating a substrate processing apparatus according to a first embodiment of the present invention.

FIG. 2 is a side perspective view illustrating the substrate processing apparatus according to the first embodiment of the present invention.

FIG. 3 is a schematic view illustrating a process furnace of the substrate processing apparatus, and surroundings of the process furnace, according to the first embodiment of the present invention.

FIG. 4 is a schematic view illustrating gas flows in the process furnace of the substrate processing apparatus according to the first embodiment of the present invention.

FIG. 5 is a flowchart illustrating a substrate processing process according to the first embodiment of the present invention.

### DETAILED DESCRIPTION OF THE PREFERRED EMBODIMENTS

### First Embodiment of the Present Invention

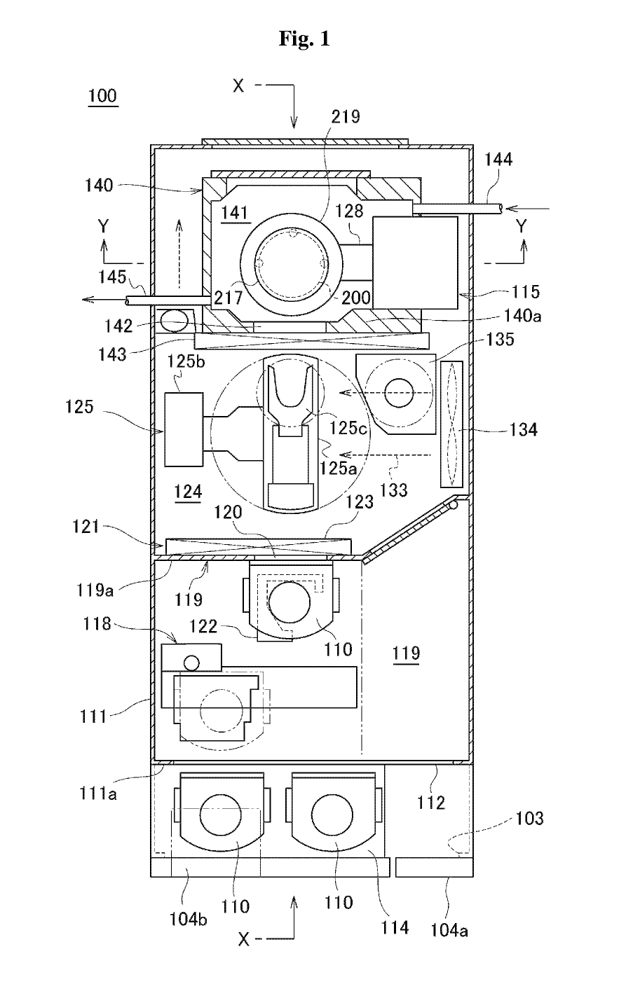

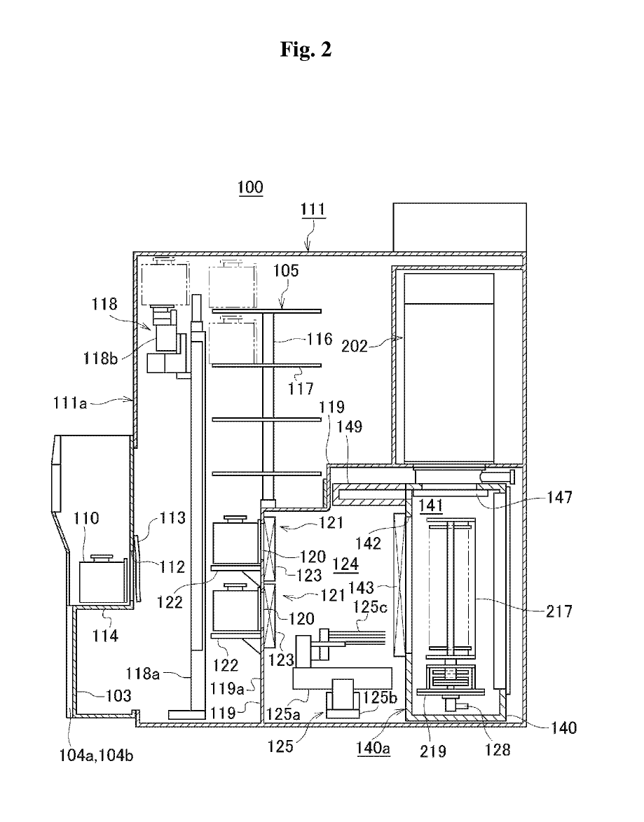

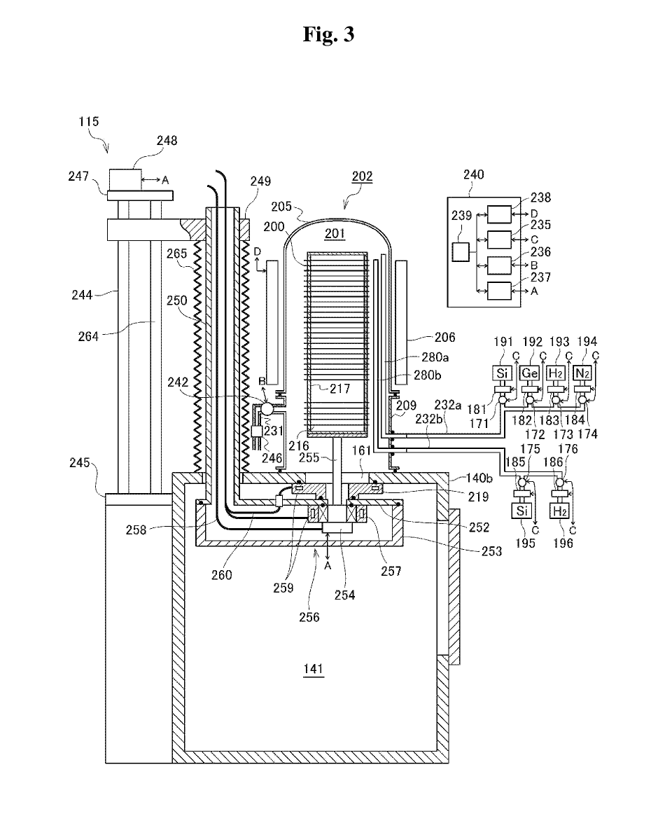

A first embodiment of the present invention will be described hereinafter with reference to the attached drawings. FIG. 1 is a plan perspective view illustrating a substrate processing apparatus according to the first embodiment of the present invention. FIG. 2 is a side perspective view (cross-sectional view taken along line X-X of FIG. 1) illustrating the substrate processing apparatus according to the first embodiment of the present invention. FIG. 3 is a schematic view (cross-sectional view taken along line Y-Y of FIG. 1) illustrating a process furnace of the substrate processing apparatus, and surroundings of the process furnace, according to the first embodiment of the present invention.

(1) Configuration of Substrate Processing Apparatus

As shown in FIG. 1 and FIG. 2, a substrate processing apparatus 100 according to the current embodiment includes a case 111. At the front side (the lower side of FIG. 1) of a front wall 111a of the case 111, a front maintenance port 103 is installed as an opening part. In addition, at the front maintenance port 103, two front maintenance doors 104a and 104b configured to open and close the front maintenance port 103 are installed.

To carry wafers 200 as substrates to the inside and outside of the case 111, pods 110 are used as substrate receiving vessels (also referred to as wafer carriers). A plurality of wafers 200 are accommodated in the pod 110. At the front wall 111a of the case 111, a pod carrying port 112 configured to carry the pod 110 to the inside and outside of the case 111 is installed such that the inside and outside of the case 111 communicate with each other. The pod carrying port 112 is opened and closed by a front shutter 113 as an opening and closing mechanism.

At the front side of the pod carrying port 112, a load port 114 is installed as a substrate accommodation unit transferring stage. The pod 110 is placed on the load port 114 such that the pod 110 is positioned on the load port 114. The pod 110 is placed on the load port 114 and carried out from the load port 114 by an in-plant carrying apparatus (not shown).

At the upper space near the center part in the case 111 in a front-to-back direction (near the center part in the case 111 shown in FIG. 2), a rotary pod shelf 105 is installed as a substrate accommodation unit rest shelf. The rotary pod shelf 105 includes a column 116 that is vertically installed and that is intermittently rotated in the horizontal plane, and a plurality of shelf plates 117 as substrate accommodation unit rest stages. The shelf plates 117 are fixed in a horizontal and radial manner to four vertically arranged stages of the column 116, respectively. The pods 110 are placed on each of the shelf plates 117.

In the case 111 between the load port 114 and the rotary pod shelves 105, a pod carrying apparatus 118 is installed as a substrate accommodation unit carrying apparatus. The pod carrying apparatus 118 includes a pod elevator 118a as a substrate accommodation unit lift mechanism configured to hold the pod 110 and move upward and downward, and a pod carrying mechanism 118b as a substrate accommodation unit carrying mechanism configured to hold the pod 110 and horizontally move. The pod carrying apparatus 118 is configured to carry the pod 110 between the load port 114, the rotary pod shelves 105, and rest stages 122 to be described later, by combined motions of the pod elevator 118a and the pod carrying mechanism 118b.

In the lower space of the case 111 from the approximate center part to the rear end part, a sub case 119 is installed. At a front wall 119a of the sub case 119 (at the center part in the case 111), as substrate carrying ports configured to carry the wafers 200 to the inside and outside of the sub case 119, a couple of wafer carrying ports 120 are installed on upper and lower stages. Pod openers 121 are respectively installed on the wafer carrying ports 120 installed on the upper and lower stages. The pod openers 121 each includes the rest stage 122 on which the pods 110 are placed, and a cap attaching-and-detaching mechanism 123 as a cover attaching-and-detaching mechanism configured to attach and detach a cap that is a cover of the pod 110. The cap attaching-and-detaching mechanism 123 attaches and detaches the cap of the pod 110 placed on the rest stage 122, so that the pod opener 121 closes and opens a wafer port of the pod 110.

A transfer chamber 124 is formed in the sub case 119. The transfer chamber 124 is air-tightly separated from the other spaces of the case 111 in which a part such as the pod carrying apparatus 118 or the rotary pod shelf 105 is installed. At the front region in the transfer chamber 124 (at the center part in the case 111), a wafer transfer mechanism 125 is installed as a substrate transfer mechanism. The wafer transfer mechanism 125 includes a wafer transfer apparatus 125a as a substrate transfer apparatus configured to place the wafers 200 on tweezers 125c as substrate holding bodies and horizontally move the tweezers 125c, and a wafer transfer apparatus elevator 125b as a substrate transfer apparatus lift mechanism configured to lift and lower the wafer transfer apparatus 125a. Combined motions of the wafer transfer apparatus 125a and the wafer transfer apparatus elevator 125b charge the wafers 200 to a boat 217 to be described later as a substrate holding tool, and discharge the wafers 200 from the boat 217.

In addition, as shown in FIG. 1, a cleaning unit 134 is installed at a side wall part in the transfer chamber 124. The cleaning unit 134 includes a supply fan and a dust filter to supply clean air 133, which is purified gas or inert gas, into the transfer chamber 124. In addition, as shown in FIG. 1, between the wafer transfer apparatus 125a and the cleaning unit 134, a notch matching device 135 is installed as a substrate aligning device configured to align a position along the circumferential direction of the wafer 200. The clean air 133 supplied from the cleaning unit 134 to the transfer chamber 124 passes through the notch matching device 135, the wafer transfer apparatus 125a, and surroundings of the boat 217 disposed in a loadlock chamber 141, and then, is sucked by a duct (not shown). Then, the gas sucked by the duct may be exhausted out of the case 111, or may circulate and arrive at a first side that is an intake side of the cleaning unit 134, and then, be purified to be supplied into the transfer chamber 124 again.

At the rear region in the transfer chamber 124 (at the rear end side in the case 111), a pressure resistant case 140 having a sealing function capable of maintaining the inner space at pressure (negative pressure) less than atmospheric pressure is installed. At the inside of the pressure resistant case 140, the loadlock chamber 141 is formed as a loadlock-type waiting chamber capable of accommodating the boat 217. At a front wall 140a of the pressure resistant case 140, a wafer carrying opening (a substrate carrying opening) 142 is installed. The loadlock chamber 141 communicates with the transfer chamber 124 by opening a gate valve 143 installed at the wafer carrying opening 142. As shown in FIG. 1, at other side walls of the pressure resistant case 140, a gas supply pipe 144 configured to supply nitrogen gas into the loadlock chamber 141, and an exhaust pipe 145 configured to perform an exhaust operation for maintaining the inner space of the loadlock chamber 141 at negative pressure are installed, respectively. At the upper side of the loadlock chamber 141, a process furnace 202 configured to process the wafers 200 is installed. At the lower end part of the process furnace 202, an opening is installed such that the inside of the process furnace 202 communicates with the inside of the transfer chamber 124. The opening installed at the process furnace 202 is opened and closed by a furnace gate valve 147 as a furnace port opening-closing mechanism. At the upper end part of the front wall 140a of the pressure resistant case 140, a furnace port gate valve cover 149 is installed.

As shown in FIG. 1, at the inside of the case 111, a boat elevator (a substrate holding tool lift mechanism) 115 configured to lift and lower the boat 217 is installed. At the lower end part of the boat elevator 115, an arm 128 is installed as a connection tool, and a seal cap 219 is horizontally installed as a cover on the upper side of the arm 128. The seal cap 219 is configured to vertically support the boat 217 from the lower part and to close the opening installed at the process furnace 202 when the boat elevator 115 moves upward. A configuration of the boat 217 will be described later.

(2) Operation of Substrate Processing Apparatus

Next, an operation of the substrate processing apparatus 100 according to the first embodiment of the present invention will now be described.

As shown in FIG. 1 and FIG. 2, when the pod 110 is placed on the load port 114, the front shutter 113 moves to open the pod carrying port 112. Then, the pod carrying apparatus 118 carries the pod 110 placed on the load port 114 into the case 111 through the pod carrying port 112. The pod 110 carried in the case 111 may be directly transferred onto the rest stage 122 at any one side of the four stages arrayed vertically, or be placed and temporarily stored on the shelf plate 117 of the rotary pod shelf 105, and then, transferred onto the rest stage 122 at any one side of the four stages arrayed vertically.

At this time, the wafer carrying port 120 of the pod opener 121 is closed by the cap attaching-and-detaching mechanism 123. In addition, the boat elevator 115 is in a lowered state, and the opening of the lower end part of the process furnace 202 is in a closed state by the furnace port gate valve 147. In addition, the cleaning unit 134 supplies the clean air 133 into the transfer chamber 124. For example, nitrogen gas as the clean air 133 is supplied into the transfer chamber 124 to fill the transfer chamber 124, so that an oxygen concentration in the transfer chamber 124 becomes, for example, 20 ppm or less, which is even lower than those of the other regions in the case 111.

The cap of the pod 110 placed on the rest stage 122 is pressed by an opening edge part of the wafer carrying port 120. Then, the cap attaching-and-detaching mechanism 123 uncovers the cap, so as to open the wafer port of the pod 110. Then, the wafer carrying opening 142 of the loadlock chamber 141 that is adjusted to the atmospheric pressure state in advance is opened by the operation of the gate valve 143. Then, the wafer 200 in the pod 110 is picked up and carried through the wafer port into the transfer chamber 124 by the tweezers 125c of the wafer transfer apparatus 125a, so that the circumferential direction of the wafer 200 is aligned by the notch matching device 135, and the wafer 200 is carried into the loadlock chamber 141 disposed at the rear side in the transfer chamber 124, and charged into the boat 217. Thereafter, the same operation is repeated to charge the wafers 200 left in the pod 110 into the boat 217.

Meanwhile, during the above-described operation, onto the rest stage 122 at another side, another pod 110 is transferred from the rotary pod shelf 105. Then, the cap attaching-and-detaching mechanism 123 uncovers the cap to open the wafer port of the pod 110.

When a predetermined number of wafers 200 are charged into the boat 217, the wafer carrying opening 142 is closed by the gate valve 143. In addition, the inner space of the loadlock chamber 141 undergoes the exhaust operation of the exhaust pipe 145 to be depressurized to the same pressure as the pressure in the process furnace 202. When the inner space of the loadlock chamber 141 reaches the pressure in the process furnace 202, the furnace port gate valve 147 moves horizontally, so that the opening of the lower end part of the process furnace 202 is opened. Subsequently, the boat elevator 115 moves upward, the boat 217 holding the wafers 200 is loaded into the process furnace 202, and the opening of the lower end part of the process furnace 202 is air-tightly closed by the seal cap 219.

After the boat 217 is loaded into the process furnace 202, an arbitrary relevant process is performed on the wafers 200 in the process furnace 202. The arbitrary relevant process will be described later. Thereafter, except for the process of aligning the circumferential direction of the wafer 200 by the notch matching device 135, in the approximate reverse sequence to the above-described sequence, the pod 110 accommodating the processed wafers 200 is carried out of the case 111.

(3) Configuration of Process Furnace

Subsequently, explanations will be given on the process furnace 202 of the substrate processing apparatus 100 relevant to the current embodiment and surrounding structures of the process furnace 202 with reference to FIG. 3.

As shown in FIG. 3, the process furnace 202 relevant to the current embodiment includes an outer tube 205 as a reaction tube. The outer tube 205 is made of a heat-resistant material such as quartz (SiO₂) or silicon carbide (SiC) and has a cylindrical shape with a closed top side and an opened bottom side. In a cylindrical hollow inner part of the outer tube 205, a process chamber 201 is formed for processing substrates such as wafers 200. The process chamber 201 is configured to accommodate the wafers 200 in a state where the wafers 200 are horizontally positioned and vertically arranged in multiple stages in the boat 217 (described later in detail).

At the outside of the outer tube 205, a heater 206 is installed coaxially with the outer tube 205. The heater 206 has a cylindrical shape. The heater 206 includes a heater wire and an insulating material installed around the heater wire. The heater 206 is vertically installed in a manner such that the heater 206 is supported on a holding body (not shown). Near the heater 206, a temperature sensor (not shown) is installed as a temperature detector for detecting the inside temperature of the process chamber 201. A temperature control unit 238 is electrically connected to the heater 206 and the temperature sensor. Based on temperature information detected by the temperature sensor, the temperature control unit 238 adjusts power supplied to the heater 206 so as to maintain the process chamber 201 at a desired temperature distribution at a desired time. Mainly, a heating member configured to heat the wafers 200 is configured by the heater 206 and the temperature sensor (not shown).

At the lower side of the outer tube 205, a manifold 209 is installed coaxially with the outer tube 205. The manifold 209 is made of metal, for example, such as stainless steel and has a cylindrical shape with opened top and bottom sides. The manifold 209 is installed to support the outer tube 205. Between the manifold 209 and the outer tube 205, an O-ring is installed as a seal member. In addition, at the lower side of the manifold 209, the loadlock chamber 141 is installed as a waiting chamber. Between the manifold 209 and a top plate 140b of the pressure resistant case 140 constituting the loadlock chamber 141, an O-ring is installed as a seal member. The manifold 209 is supported by the top plate 140b such that the outer tube 205 can be vertically fixed. The outer tube 205 and the manifold 209 constitute a reaction vessel. In the top plate 140b, a furnace port 161 is formed as an opening part of the process furnace 202.

A film-forming gas supply nozzle 280a in the process chamber 201, and a coating gas supply nozzle 280b in the process chamber 201 are connected to a side wall of the manifold 209 such that the film-forming gas supply nozzle 280a and the coating gas supply nozzle 280b independently pass through the side wall of the manifold 209. Downstream sides of the film-forming gas supply nozzle 280a and the coating gas supply nozzle 280b are installed along an inner wall of the process chamber 201, for example, installed vertically. At downstream ends (upper ends) of the film-forming gas supply nozzle 280a and the coating gas supply nozzle 280b, gas ejection ports are installed. That is, in the current embodiment, instead of installing an inner tube, the film-forming gas supply nozzle 280a and the coating gas supply nozzle 280b are used to supply various types of gas from the upper part in the process chamber 201. Upstream sides of the film-forming gas supply nozzle 280a and the coating gas supply nozzle 280b horizontally penetrate the side wall of the manifold 209, so as to protrude out of the outer periphery of the manifold 209. The film-forming gas supply nozzle 280a and the coating gas supply nozzle 280b are made of a material such as quartz (SiO₂) or silicon carbide (SiC).

A film-forming gas supply pipe 232a is connected to an upstream end of the film-forming gas supply nozzle 280a. The film-forming gas supply pipe 232a is divided into four parts at the upstream side. The divided four parts of the film-forming gas supply pipe 232a are respectively connected to a first gas supply source 191, a second gas supply source 192, a third gas supply source 193, and a fourth gas supply source 194 in a state where valves 171, 172, 173, and 174, and mass flow controllers (MFCs) 181, 182, 183, and 184 as gas flowrate control devices are disposed between the divided four parts of the film-forming gas supply pipe 232a and the first through four gas supply sources 191, 192, 193, and 194. The first gas supply source 191 is configured to supply Si element-containing gas, for example, such as silane (SiH₄), disilane (Si₂H₆), and dichlorosilane (SiH₂Cl₂). The second gas supply source 192 is configured to supply Ge element-containing gas, for example, such as germane (GeH₄). The third gas supply source 193 is configured to supply H₂ gas. The fourth gas supply source 194 is configured to supply, for example, N₂ gas as purge gas. The valves 171, 172, and 173 are opened to supply mixed gas of Si element-containing gas, Ge element-containing gas, and H₂ gas into the process chamber 201 as film-forming gas. The composition or flowrate of film-forming gas can be adjusted by the MFCs 181, 182, and 183. In addition, the valves 171, 172, and 173 are closed and the valve 174 is opened to purge the inside of the film-forming gas supply nozzle 280a by N₂ gas as purge gas. The flowrate of purge gas can be adjusted by the MFC 184. Mainly, the film-forming gas supply nozzle 280a, the film-forming gas supply pipe 232a, the valves 171, 172, 173, and 174, the MFCs 181, 182, 183, and 184, the first gas supply source 191, the second gas supply source 192, the third gas supply source 193, and the fourth gas supply source 194 constitute a film-forming gas supply member.

A coating gas supply pipe 232b is connected to an upstream end of the coating gas supply nozzle 280b. The coating gas supply pipe 232b is divided into two parts at the upstream side. The divided two parts of the coating gas supply pipe 232b are respectively connected to a fifth gas supply source 195 and a sixth gas supply source 196 in a state where valves 175 and 176, and MFCs 185 and 186 as gas flowrate control devices are disposed between the divided two parts of the coating gas supply pipe 232b and the fifth and sixth gas supply sources 195 and 196. The fifth gas supply source 195 is configured to supply Si element-containing gas, for example, such as silane (SiH₄), disilane (Si₂H₆), and dichlorosilane (SiH₂Cl₂). The sixth gas supply source 196 is configured to supply H₂ gas. The valves 175 and 176 are opened to supply mixed gas of Si element-containing gas and H₂ gas into the process chamber 201 as coating gas. The composition or flowrate of coating gas may be adjusted by the MFCs 185 and 186. Mainly, the coating gas supply nozzle 280b, the coating gas supply pipe 232b, the valves 175 and 176, the MFCs 185 and 186, the fifth gas supply source 195, and the sixth gas supply source 196 constitute a coating gas supply member.

A gas flowrate control unit 235 is electrically connected to the MFCs 181, 182, 183, 184, 185, and 186, and the valves 171, 172, 173, 174, 175, and 176. The gas flowrate control unit 235 controls each of the MFCs 181, 182, 183, 184, 185, and 186, and the valves 171, 172, 173, 174, 175, and 176 to supply gas at a desired time in a desired composition at a desired flowrate from the film-forming gas supply member and the coating gas supply member into the process chamber 201.

In addition, a gas exhaust pipe 231 is connected to the side wall of the manifold 209. A vacuum exhaust device 246 such as a vacuum pump is connected to a downstream side of the gas exhaust pipe 231 with an auto pressure controller (APC) valve 242 being disposed therebetween. The APC valve 242 is configured as a pressure regulator to adjust the pressure in the process chamber 201 according to an opened area of the pressure regulator. At the inside of the gas exhaust pipe 231 at an upstream side of the APC valve 242, a pressure sensor (not shown) is installed as a pressure detection member configured to detect the pressure in the process chamber 201. The position of the pressure sensor is not limited to the inside of the gas exhaust pipe 231, and thus, the pressure sensor may be disposed at the inside of the process chamber 201. A pressure control unit 236 is electrically connected to the pressure sensor and the APC valve 242. The pressure control unit 236 adjusts the opened area of the APC valve 242 based on pressure detected by the pressure sensor, and controls the pressure in the process chamber 201 to be a desired pressure at a desired time. Mainly, the gas exhaust pipe 231, the APC valve 242, the vacuum exhaust device 246, and the pressure sensor (not shown) constitute an exhaust member configured to exhaust atmosphere in the process chamber 201.

In addition, as described above, at the outer surface of the pressure resistant case 140 constituting the loadlock chamber 141, the boat elevator 115 is installed. The boat elevator 115 includes a lower base member 245, a guide shaft 264, a ball screw 244, an upper base member 247, a lift motor 248, a lift base member 252, and a bellows 265. The lower base member 245 is horizontally fixed to the outer surface of the sidewall of the loadlock chamber 141. The guide shaft 264 fitted to a lift stage 249, and the ball screw 244 thread-coupled to the lift stage 249 are vertically installed on the lower base member 245. The upper base member 247 is horizontally fixed to the upper ends of the guide shaft 264 and the ball screw 244. The ball screw 244 is configured to be rotated by the lift motor 248 installed on the upper base member 247. In addition, the guide shaft 264 is configured to allow vertical movement of the lift stage 249 but suppress horizontal rotation of the lift stage 249. The lift stage 249 is configured to be moved upward and downward by rotating the ball screw 244.

A hollow lift shaft 250 is vertically fixed to the lift stage 249. The joint between the lift stage 249 and the lift shaft 250 is airtight. The lift shaft 250 is configured to be moved upward and downward together with the lift stage 249. The lower end part of the lift shaft 250 penetrates the top plate 140b of the loadlock chamber 141. A penetration hole is formed in the top plate 140b, and the inner diameter of the hole is adjusted to be greater than the outer diameter of the lift shaft 250 so as to prevent the lift shaft 250 from making contact with the top plate 140b. Between the loadlock chamber 141 and the lift stage 249, the bellows 265 made of a hollow flexible material is installed to surround the lift shaft 250. The joint between the lift stage 249 and the bellows 265, and the joint between the top plate 140b and the bellows 265 are airtight such that the inside of the loadlock chamber 141 can be air-tightly maintained. The bellows 265 is sufficiently flexible for coping with the movement of the lift stage 249. The inner diameter of the bellows 265 is sufficiently larger than the outer diameter of the lift shaft 250 for prevent the bellows 265 making contact with the lift shaft 250.

The lower end of the lift shaft 250 protrudes to the inside of the loadlock chamber 141, and the lift base member 252 is horizontally fixed to the lower end of the lift shaft 250. The joint between the lift shaft 250 and the lift base member 252 is configured to be airtight. On the top surface of the lift base member 252, the seal cap 219 is air-tightly installed with a seal member such as an O-ring being disposed therebetween. For example, the seal cap 219 is made of a metal such as stainless steel and has a disk shape. If the ball screw 244 is rotated by operating the lift motor 248, the lift stage 249, the lift shaft 250, the lift base member 252, and the seal cap 219 can be lifted so as to load the boat 217 into the process furnace 202 (boat loading) and close the furnace port 261 (opening) of the process furnace 202 by using the seal cap 219. In addition, if the ball screw 244 is rotated by operating the lift motor 248, the lift stage 249, the lift shaft 250, the lift base member 252, and the seal cap 219 can be lowered so as to unload the boat 217 from the process chamber 201 (boat unloading). A driving control unit 237 is electrically connected to the lift motor 248. The driving control unit 237 controls the boat elevator 115 so that a desired operation of the boat elevator 115 can be carried out at a desired time.

On the bottom surface of the lift base member 252, a driving unit cover 253 is air-tightly installed with a seal member such as an O-ring between disposed therebetween. A driving unit accommodating case 256 is constituted by the lift base member 252 and the driving unit cover 253. The inside of the driving unit accommodating case 256 is isolated from the inside atmosphere of the loadlock chamber 141. Inside the driving unit accommodating case 256, a rotary mechanism 254 is installed. A power supply cable 258 is connected to the rotary mechanism 254. The power supply cable 258 extends from the upper end of the lift shaft 250 to the rotary mechanism 254 through the inside of the lift shaft 250 so as to supply power to the rotary mechanism 254. The upper end part of a rotation shaft 255 of the rotary mechanism 254 is configured to penetrate the seal cap 219 and support the bottom side of the boat 217 used as a substrate holding unit. By operating the rotary mechanism 254, wafers 200 held in the boat 217 can be rotated in the process chamber 201. The driving control unit 237 is electrically connected to the rotary mechanism 254. The driving control unit 237 controls the rotary mechanism 254 such that a desired operation of the rotary mechanism 254 can be performed at a desired time.

In addition, a cooling mechanism 257 is installed in the driving unit accommodating case 256 around the rotary mechanism 254. Cooling passages 259 are formed in the cooling mechanism 257 and the seal cap 219. Coolant pipes 260 are connected to the cooling passages 259 for supplying coolant to the cooling passages 259. The coolant pipes 260 extend from the upper end of the lift shaft 250 to the cooling passages 259 through the inside of the lift shaft 250 and are configured to supply coolant to the cooling passages 259.

The boat 217 used as a substrate holding unit is made of a heat-resistant material such as quartz (SiO₂) or silicon carbide (SiC) and is configured to hold a plurality of wafers 200 in a state where the wafers 200 are horizontally oriented and arranged in multiple stages with their centers being aligned. At the lower part of the boat 217, a plurality of disk-shaped insulation plates 216 functioning as insulating members and made of a heat-resistant material such as quartz (SiO₂) or silicon carbide (SiC) are horizontally oriented and arranged in multiple stages. Owing to the insulation plates 216, heat transfer from the heater 206 to the manifold 209 is difficult.

Furthermore, the substrate processing apparatus 100 relevant to the current embodiment includes a controller 240 as a control unit. The controller 240 includes a main control unit 239, and the main control unit 239 includes a central processing unit (CPU), a memory, a storage device such as a hard disk drive (HDD), a manipulation unit, and an input/output unit. The main control unit 239 is electrically connected to the gas flowrate control unit 235, the pressure control unit 236, the driving control unit 237, the temperature control unit 238, the lift motor 248 of the boat elevator 115, and the rotary mechanism 254, as described above. The main control unit 239 is configured to control the overall operation of the substrate processing apparatus 100. The controller 240 executes a control to perform a process of holding the wafers 200 in a state where the wafers 200 are spaced a predetermined distance from each other in a stacked shape to load the wafers 200 into the process chamber 201, a process of supplying coating gas by the coating gas supply nozzle 280b to coat a quartz member in the process chamber 201, a process of supplying film-forming gas by the film-forming gas supply nozzle 280a to form thin films on the wafers 200, and a process of unloading the wafers 200 out of the process chamber 201. The relevant operations will be described later.

(4) Substrate Processing Process

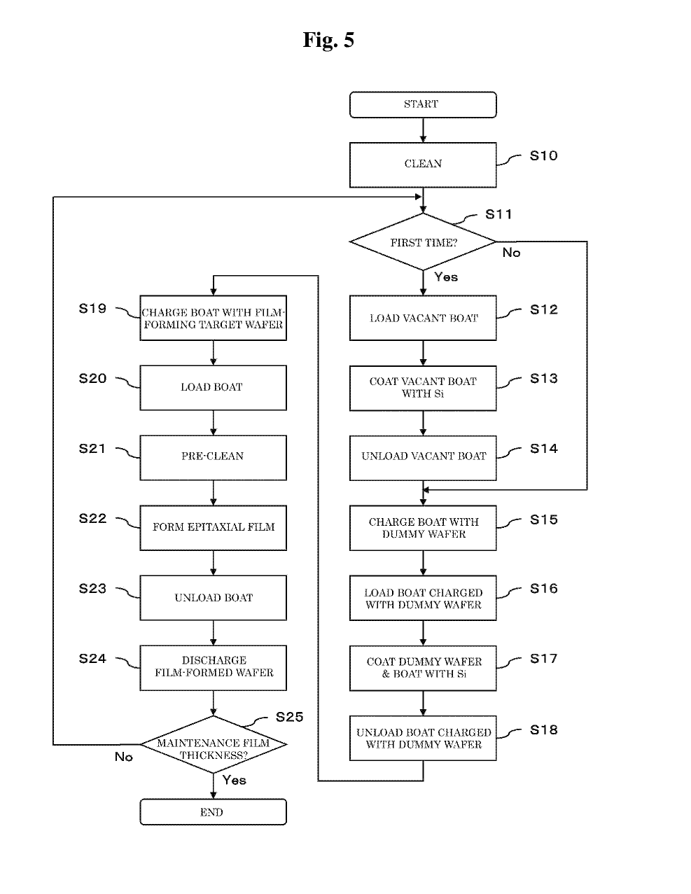

Subsequently, as one of semiconductor device manufacturing processes, a substrate processing process of selectively growing an SiGe epitaxial film on a surface of the wafer 200 will now be described with reference to FIG. 5. FIG. 5 is a flowchart illustrating a substrate processing process according to the first embodiment of the present invention.

The substrate processing process is performed by the above-described substrate processing apparatus 100. In addition, in the following descriptions, the operation of each part constituting the substrate processing apparatus 100 is controlled by the controller 240.

(Cleaning Operation S10)

First, the inner wall of the process chamber 201 or the surface of the boat 217 is cleaned. Specifically, a vacant boat 217 (boat 217 in which wafers 200 are not charged yet) is loaded into the process chamber 201 (boat loading), and the vacuum exhaust device 246 is operated to exhaust atmosphere in the process chamber 201.

In addition, an etching gas supply member (not shown) is used to supply etching gas, for example, such as ClF₃ gas or F₂ gas into the process chamber 201, and deposits and foreign substances adsorbed to the inner wall of the process chamber 201 or the surface of the boat 217 are etched out. After a predetermined time is elapsed, the supplying of etching gas into the process chamber 201 is stopped, and etching gas or etching products left in the process chamber 201 are exhausted. At this time, in the state where the valves 171, 172, and 173 are closed, the valve 174 is opened, and N₂ gas as purge gas is supplied from the film-forming gas supply nozzle 280a into the process chamber 201, so as to promote discharging of materials such as etching gas or etching products from the inside of the process chamber 201. Thereafter, the opened area of the APC valve 242 is feedback controlled to maintain the inside of the process chamber 201 and the inside of the loadlock chamber 141 at an identical pressure, and the lift motor 248 is driven to unload the boat 217 from the inside of the process chamber 201, so that the boat 217 is put in the lowered state.

(First-Time Process Determination Process S11)

Subsequently, it is determined whether a film forming process to be performed next time is the first-time film forming process to be performed just after the cleaning operation. Here, if a film forming process to be performed next time is the first-time film forming process, it is determined that, prior to the film forming process, coating of the quartz member with Si in the process chamber 201 is necessary, so that an operation S12 to be described later is performed (branched to ‘Yes’ from the operation S11 of FIG. 5).

(Vacant Boat Loading Operation S12)

The lift motor 248 is driven to load a vacant boat 217 (boat 217 in which wafers 200 are not charged yet) into the process chamber 201 (boat loading), and simultaneously, the furnace port 161 as the opening part of the process furnace 202 is closed by the seal cap 219. Then, the boat 217 is rotated by the rotary mechanism 254.

(Coating Operation S13)

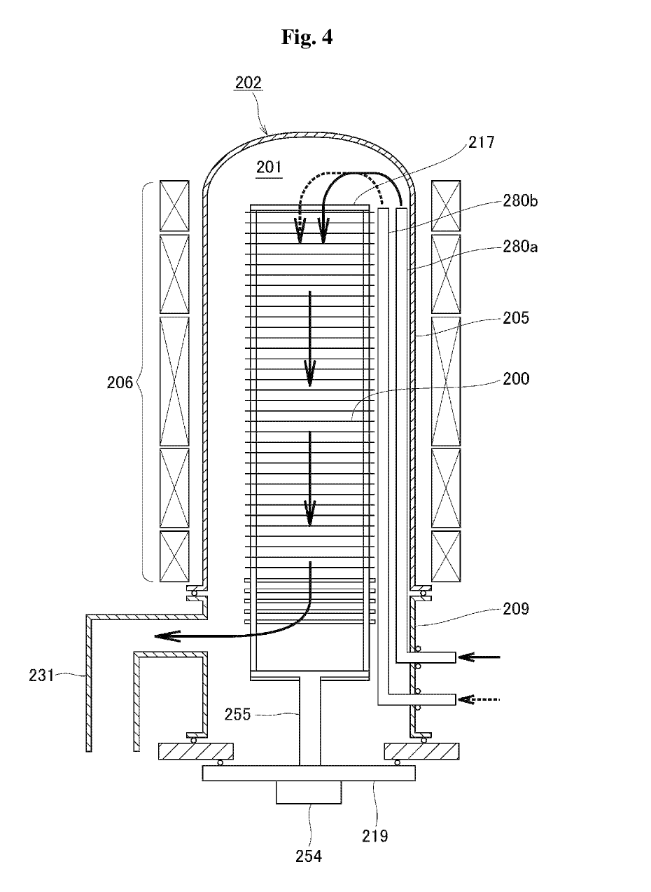

Subsequently, the opened area of the APC valve 242 is feedback controlled to maintain the process chamber 201 at a predetermined pressure (coating process pressure). In addition, based on temperature information detected by the temperature sensor (not shown), power supplied to the heater 206 is feedback controlled so as to maintain the process chamber 201 at a desired temperature distribution. Specifically, the inner wall of the process chamber 201 or the surface of the boat 217 is maintained at a temperature, for example, ranging from 650° C. to 680° C. Then, the valves 175 and 176 are opened to supply mixed gas of Si element-containing gas and H₂ gas as coating gas into the process chamber 201. At this time, the composition or flowrate of the coating gas is adjusted by the MFCs 185 and 186. The coating gas introduced into the process chamber 201 flows along an arrow depicted with dashed lines in FIG. 4, from the upper side of the process chamber 201 to the lower side of the process chamber 201, and is exhausted from the gas exhaust pipe 231. When the coating gas passes through the inside of the process chamber 201, the coating gas is in contact with the inner wall of the process chamber 201 or the surface of the boat 217. Then, at the inner wall of the process chamber 201 or at the surface of the boat 217, an Si thin film made of a material such as poly crystalline Si (Poly-Si) is formed. After a predetermined time is elapsed, the valves 175 and 176 are closed to stop the supplying of the coating gas into the process chamber 201, and materials such as coating gas left in the process chamber 201 are exhausted. Accordingly, the inner wall of the process chamber 201 or the surface of the boat 217 is covered (coated) with an Si thin film having a film thickness, for example, ranging from about 30 nm to about 1 nm.

Hereby, in a next-time SiGe epitaxial film growth, contamination of the wafers 200 due to the surface of the quartz member (such as the inner wall of an outer tube 203 or the surface of the boat 217) installed in the process chamber 201 can be suppressed. In addition, the inner wall of the process chamber 201 (the outer tube 203) is coated with an Si thin film so as to improve the heat conduction efficiency of the outer tube 203, thus improving the quality or productivity in processing a substrate.

As such, in the current embodiment, the supplying of coating gas into the process chamber 201 is performed by the coating gas supply member that is installed independently from the film-forming gas supply member. That is, in the current embodiment, coating gas is supplied not through the film-forming gas supply nozzle 280a, but through the coating gas supply nozzle 280b. Thus, an Si thin film is inhibited from being formed on the inner wall of the film-forming gas supply nozzle 280a. That is, since only quartz (SiO₂) or silicon carbide (SiC) is mainly exposed at the inner wall surface of the film-forming gas supply nozzle 280a, a state where an Si film as a base of an epitaxial growth almost does not exist is maintained. In addition, even when an operation S22 to be described later is repeated (even when the supplying of film-forming gas to the inside of the film-forming gas supply nozzle 280a is repeated), the growth of an SiGe epitaxial film on the inner wall surface of the film-forming gas supply nozzle 280a is suppressed. As a result, closing or breakage of the film-forming gas supply nozzle 280a can be suppressed. In addition, in the film-forming gas supply nozzle 280a, the consumption of film-forming gas is suppressed to easily perform the flowrate control of film-forming gas supplied to the wafers 200, and film-forming gas is stably supplied to improve the quality in processing a substrate.

In the current embodiment, while the valves 175 and 176 are opened to supply coating gas to the inside of the process chamber 201, or while coating gas is left at the inside of the process chamber 201, the valve 174 may be opened to purge the inside of the film-forming gas supply nozzle 280a by N₂ gas as purge gas. Hereby, since the invasion of coating gas to the inside of the film-forming gas supply nozzle 280a is effectively suppressed, the forming of an Si thin film on the inner wall of the film-forming gas supply nozzle 280a can be further suppressed. In addition, when a material such as coating gas left in the process chamber 201 is exhausted, purge gas is supplied to the inside of the process chamber 201, so as to promote the exhausting of coating gas directed from the inside of the process chamber 201 to the film-forming gas supply nozzle 280a. Meanwhile, the flowrate of purge gas is adjusted by the MFC 184.

(Boat Unloading Operation S14)

The opened area of the APC valve 242 is feedback controlled to maintain the inside of the process chamber 201 and the inside of the loadlock chamber 141 at an identical pressure, and the lift motor 248 is driven to unload the boat 217 from the inside of the process chamber 201, so that the boat 217 is put in the lowered state.

(Dummy Wafer Charging Operation S15)

Next, dummy wafers are charged to the boat 217 after the coating operation. At the upper and lower sides of a region where a process target wafer 200 on which an SiGe film is formed is charged, an arbitrary number of dummy wafers, for example, ten dummy wafers at each of the upper and lower sides, totally, twenty dummy wafers are charged. Since the dummy wafers are charged, when gas is introduced from the coating gas supply nozzle 280b, film-forming gas can arrive at a wafer in a sufficiently active state. In addition, since the dummy wafers are charged, a film-forming target wafer can be protected against contamination generated from an exhaust system, or particles are adsorbed to the dummy wafers to suppress the particles from being adsorbed to a film-forming target wafer.

(Charged Dummy Wafer Boat Loading Operation S16)

In the same manner as in the vacant boat loading operation S12, the boat 217 charged with the dummy wafers is loaded into the process chamber 201 (boat loading), and simultaneously, the furnace port 161 as the opening part of the process furnace 202 is closed by the seal cap 219. Then, the boat 217 is rotated by the rotary mechanism 254.

(Dummy Wafer Si Coating Operation S17)

In the same manner as in the coating operation S13, an Si coating operation is performed on the boat 217 charged with the dummy wafers. At this time, the charged dummy wafers are coated with Si to suppress defective formation of a film due to the dummy wafers.

(Charged Dummy Wafer Boat Unloading Operation S18)

In the same manner as in the boat unloading operation S14, the boat 217 charged with the dummy wafers coated with Si is unloaded.

(Wafer Charging Operation S19)

The wafer transfer mechanism 125 charges a plurality of process target wafers 200 to the boat 217 disposed in the lowered state. The boat 217 holds the plurality of wafers 200 in a state where the wafers 200 are spaced a predetermined distance from each other in a stacked shape. Meanwhile, at least both an Si surface and an insulating film surface are exposed on the surface of the wafer 200. Specifically, since an insulating film made of a material, for example, such as SiO₂ or SiN is formed on at least one portion of the outer surface of the wafer 200 configured as a silicon wafer, an Si surface and an insulating film surface are independently exposed. Meanwhile, the Si surface exposed on the surface of the wafer 200 functions as a base on which an SiGe epitaxial film to be described later is grown.

(Boat Loading Operation S20)

When the charging of the wafers 200 into the boat 217 is completed, the lift motor 248 is driven to load the boat 217 holding a predetermined number of wafers 200 into the process chamber 201 (boat loading) as shown in FIG. 3, and simultaneously, the furnace port 161 as the opening part of the process furnace 202 is closed by the seal cap 219. After that, the boat 217 is rotated by the rotary mechanism 254.

(Pre-Cleaning Operation S21)

Subsequently, before forming a film, to remove leavings left on the surface of a wafer, for example, to remove a material such as an oxide film or an organic material, a wafer pre-cleaning operation is performed. In a hydrogen baking operation as one of pre-cleaning operations, the opened area of the APC valve 242 is feedback controlled, and the inside of the process chamber 201 is maintained at a predetermined pressure (H₂ bake process pressure). In addition, based on temperature information detected by the temperature sensor (not shown), power supplied to the heater 206 is feedback controlled so as to maintain the process chamber 201 at a desired temperature distribution. Specifically, the surface temperature of the wafer 200 is maintained, for example, at a range from 700° C. to 1000° C., or preferably at 800° C. or greater. Then, the valve 173 is opened to supply H₂ gas as reduction gas into the process chamber 201. At this time, the MFC 183 is controlled such that the flowrate of H₂ gas is, for example, about 5 slm, or preferably 20 slm or greater. H₂ gas introduced into the process chamber 201 flows along arrows depicted with solid lines in FIG. 4, from the upper side of the process chamber 201 to the lower side of the process chamber 201, and is exhausted from the gas exhaust pipe 231. When the H₂ gas passes through the inside of the process chamber 201, the H₂ gas is in contact with the surfaces of the wafers 200 to reduce oxygen (O) at the surfaces of the wafers 200.

For example, after about 30 minutes, the valve 173 is closed to stop the supplying of the H₂ gas into the process chamber 201, and a material such as H₂ gas or a reaction product left in the process chamber 201 is exhausted.

At this time, when the valve 174 is opened to supply N₂ gas as purge gas into the process chamber 201, the exhausting of a material such as film-forming gas or a reaction product from the inside of the process chamber 201 is promoted. Accordingly, the oxygen (O) concentration of the surface of the wafer 200 is reduced, for example, to 10¹⁷ atoms/cm³.

(SiGe Epitaxial Film Selection Formation Operation S22)

Subsequently, the opened area of the APC valve 242 is feedback controlled to maintain the process chamber 201 at a predetermined pressure (film forming process pressure). In addition, based on temperature information detected by the temperature sensor (not shown), power supplied to the heater 206 is feedback controlled so as to maintain the process chamber 201 at a desired temperature distribution. Specifically, the surface temperature of the wafer 200 is maintained, for example, at a range from 450° C. to 600° C. Then, the valves 171, 172, and 173 are opened to supply mixed gas of Si element-containing gas, Ge element-containing gas, and H₂ gas into the process chamber 201 as film-forming gas. The composition or flowrate of film-forming gas may be adjusted by the MFCs 181, 182, and 183. Film-forming gas introduced into the process chamber 201 flows along the arrows depicted with the solid lines in FIG. 4, from the upper side of the process chamber 201 to the lower side of the process chamber 201, is supplied to the surfaces of the wafers 200, and is exhausted from the gas exhaust pipe 231.

When the film-forming gas passes through the inside of the process chamber 201, the film-forming gas is in contact with the surfaces of the wafers 200. Then, on the surfaces of the wafers 200, using Si surfaces as a base, SiGe epitaxial films are selectively grown.

In a film forming operation using an epitaxial growth method such as the current embodiment, characteristics such as the quality of a formed film, that is, the morphology of a film or uniformity in film quality and film thickness significantly depend on factors such as a channel through which film-forming gas flows, velocity of film-forming gas, and a composition ratio of film-forming gas. In the current embodiment, the film-forming gas supply nozzle 280a ejects film-forming gas from the gas ejection port installed at the downstream end (upper end) to form the flow of film-forming gas from the upper side of the process chamber 201 to the lower side of the process chamber 201, so that the above behavior of film-forming gas can be controlled.

After a predetermined time is elapsed, the valves 171, 172, and 173 are closed to stop the supplying of film-forming gas into the process chamber 201, and a material such as film-forming gas or a reaction product left in the process chamber 201 is exhausted. At this time, when the valve 174 is opened to supply N₂ gas as purge gas into the process chamber 201, the exhausting of a material such as film-forming gas or a reaction product from the inside of the process chamber 201 is promoted.

(Boat Unloading Operation S23)

Subsequently, the opened area of the APC valve 242 is feedback controlled to maintain the inside of the process chamber 201 and the inside of the loadlock chamber 141 at an identical pressure, and the lift motor 248 is driven to unload the boat 217 from the inside of the process chamber 201, so that the boat 217 is put in the lowered state.

(Wafer Discharging Operation S24)

Subsequently, the wafer transfer mechanism 125 discharges the processed wafers 200 from the boat 217 disposed in the lowered state (wafer discharging), and accommodates the processed wafers 200 in the pod 110.

(Maintenance Film Thickness Determination Operation S25)

Subsequently, it is determined whether an accumulation film thickness on the boat 217 in a just-previous film forming process reaches a maintenance film thickness. If an accumulation film thickness on the boat 217 due to the just-previous film-forming process does not reach a maintenance film thickness (If No), the above-described dummy wafer charging operation S15 and the following operations are performed again.

After the SiGe epitaxial film forming operation, by performing the above-described Si coating operation (the operations S15 through S18) on a dummy wafer, for example, by the previous SiGe epitaxial film forming operation, a reaction product such as GeO or a foreign substance may be adsorbed to the inner wall of the process chamber 201 or the surface of the boat 217. According to the current embodiment, by coating a part such as the inner wall of the process chamber 201 or the surface of the boat 217 with an Si thin film, such a reaction product or foreign substance is detached from a part such as the inner wall of the process chamber 201 or the surface of the boat 217, and can be suppressed from being scattered at the inside of the process chamber 201, so that contamination of the wafers 200 can be suppressed.

If an accumulation film thickness reaches the maintenance film thickness (If Yes), the process is performed from the cleaning operation S10 that is the first-time operation.

(5) Effects Relevant to the Current Embodiment

According to the current embodiment, one or more effects are attained as follows.

According to the current embodiment, the supplying of coating gas into the process chamber 201 is performed by the coating gas supply member installed independently from the film-forming gas supply member. That is, in the current embodiment, coating gas is supplied not through the film-forming gas supply nozzle 280a but through the coating gas supply nozzle 280b. Thus, the forming of an Si thin film on the inner wall of the film-forming gas supply nozzle 280a can be suppressed. That is, since only quartz (SiO₂) or silicon carbide (SiC) is exposed mainly at the inner wall surface of the film-forming gas supply nozzle 280a, a state where an Si film as a base of an epitaxial growth almost does not exist is maintained. In addition, even when the above-described operation S22 is repeated (even when the supplying of film-forming gas to the inside of the film-forming gas supply nozzle 280a is repeated), the growth of a SiGe epitaxial film on the inner wall surface of the film-forming gas supply nozzle 280a is suppressed. As a result, closing or breakage of the film-forming gas supply nozzle 280a can be suppressed. In addition, in the film-forming gas supply nozzle 280a, the consumption of film-forming gas can be suppressed to easily perform the flowrate control of film-forming gas supplied to the wafers 200, and film-forming gas is stably supplied to improve the quality in processing a substrate.

In addition, according to the current embodiment, by using the film-forming gas supply nozzle 280a, film-forming gas is supplied to form an epitaxial film on the substrate. As such, by using the film-forming gas supply nozzle 280a at which only quartz (SiO₂) or silicon carbide (SiC) is mainly exposed, film-forming gas is supplied, so that the flowrate and composition ratio of film-forming gas can be accurately controlled so as to improve the quality of an epitaxial film to be formed.

In addition, in the current embodiment, while the valves 175 and 176 are opened to supply coating gas to the inside of the process chamber 201, or while coating gas is left at the inside of the process chamber 201, the valve 174 is opened to purge the inside of the film-forming gas supply nozzle 280a by N₂ gas as purge gas. Hereby, since the invasion of coating gas to the inside of the film-forming gas supply nozzle 280a can be effectively suppressed, the forming of an Si thin film on the inner wall of the film-forming gas supply nozzle 280a can be further suppressed. Thus, a maintenance cycle for cleaning an Si thin film from the inner wall of the film-forming gas supply nozzle 280a can be extended.

In addition, according to the current embodiment, by performed the above-described coating operation S13, the inner wall of the process chamber 201 or the outer surface of the boat 217 is covered (coated) with an Si thin film having a film thickness, for example, ranging from about 30 nm to about 1 μm. Hereby, in a next-time SiGe epitaxial film growth, contamination of the wafers 200 due to the surface of the quartz member (such as the inner wall of the outer tube 203 or the surface of the boat 217) installed in the process chamber 201 can be suppressed. In addition, for example, by the previous SiGe epitaxial film forming process, a reaction product such as GeO or a foreign substance adsorbed to a part such as the inner wall of the process chamber 201 or the surface of the boat 217 may be left in the next-time SiGe epitaxial film growth is performed. According to the current embodiment, by coating the inner wall of the process chamber 201 or the surface of the boat 217 with an Si thin film, such a reaction product or foreign substance is detached from the inner wall of the process chamber 201 or the surface of the boat 217, and can be suppressed from being scattered at the inside of the process chamber 201, so that contamination of the wafers 200 can be suppressed. In addition, the inner wall of the process chamber 201 (the outer tube 203) is coated with an Si thin film so as to improve the heat conduction efficiency of the outer tube 203, thus improving the quality or productivity in processing a substrate.

In addition, in the cleaning operation S10, the pre-cleaning operation S21, the SiGe epitaxial film selection formation operation S22, the vacant boat Si coating operation S13, and the dummy wafer and boat Si coating operation S17 according to the current embodiment, the valve 174 is opened to supply N₂ gas as purge gas into the process chamber 201, thus promoting the exhausting of a material such as leftover gas from the inside of the process chamber 201. Also, the productivity in processing substrates can be improved.

In addition, according to the current embodiment, in the first-time determination operation S11, it is determined whether a film forming process to be performed next time is the first-time film forming process. If a film forming process to be performed next time is not the first-time film forming process, it is determined that the coating of the quartz member in the process chamber 201 prior to the film forming process is unnecessary, so that, without performing the above-described operations S12 through S14, the operation S15 and the following operations are performed. Hereby, the productivity in processing substrates can be improved.

In addition, according to the current embodiment, without installing an inner tube, the film-forming gas supply nozzle 280a and the coating gas supply nozzle 280b are used to supply various types of film-forming gas from the upper side in the process chamber 201. Thus, the diffusion of contaminants left at the lower side in the process chamber 201 can be suppressed. As a result, adsorption of foreign substances to parts such as the surfaces of wafers 200 is suppressed to improve the productivity in processing substrates.

### Second Embodiment of the Present Invention

Next, a substrate processing apparatus relevant to the second embodiment of the present invention will now be described. In the substrate processing apparatus relevant to the current embodiment, a configuration relevant to a coating gas supply member is different from that of the first embodiment. Thus, references for the other configurations will be made to the descriptions relevant to the first embodiment and FIG. 3, and detailed descriptions thereof will be omitted.

In the current embodiment, the diameter of the coating gas supply nozzle 280b is greater than the diameter of the film-forming gas supply nozzle 280a. Alternatively, in the coating gas supply nozzle 280b, only the diameter of the downstream side that is vertically extended may be greater than the diameter of the downstream side of the film-forming gas supply nozzle 280a. Alternatively, according to the diameter of the coating gas supply nozzle 280b, to obtain the optimal flow velocity and flowrate of coating gas, the caliber of the gas ejection port installed at the downstream end (upper end) of the coating gas supply nozzle 280b may be optimized.

According to the current embodiment, one or more effects are attained as follows.

Also in the current embodiment, the same effects as in the previous embodiment are attained. Furthermore, according to the current embodiment, the diameter of the coating gas supply nozzle 280b is greater than the diameter of the film-forming gas supply nozzle 280a. Hereby, the maintenance cycle can be extended. When coating gas is supplied, an Si thin film is slowly formed on the inner wall of the coating gas supply nozzle 280b. Thus, when the thickness of an Si thin film reaches a predetermined thickness, to prevent the closing or breakage of the coating gas supply nozzle 280b, maintenance is necessary as the removal of the Si thin film or the replacement of the coating gas supply nozzle 280b. By increasing the size of the coating gas supply nozzle 280b, the maintenance cycle can be extended, and the maintenance frequency can be decreased.

### Other Embodiments of the Present Invention

In the above-described embodiments, since at least both an Si surface and an insulating film surface are exposed on the surface of the wafer 200, an epitaxial film is selectively deposited on the Si surface, but the present invention is not limited thereto. That is, the present invention is not limited to the case where an epitaxial film is selectively grown, and thus, is very suitably applicable to the case where an epitaxial film is grown on the entire surface of the wafer 200. In addition, the present invention is not limited to the selective epitaxial growth, and thus, is very suitably applicable to a selective poly crystalline growth (Poly growth) and the other selective growths.

In the above-described embodiments, as film-forming gas, mixed gas of Si element-containing gas, Ge element-containing gas, and H₂ gas is used to grow an SiGe epitaxial film on a wafer 200, but the present invention is not limited thereto. For example, the present invention is very suitable applicable to the case where, as film-forming gas, mixed gas of Si element-containing gas and H₂ gas is used to grow an Si epitaxial film on a wafer 200. In addition, the present invention is not limited to the shape in which the film-forming gas supply pipe 232a is divided into four parts as in the above-described embodiment, and thus, the film-forming gas supply pipe 232a may be divided into three or less parts, or into five or more parts, according to the types of supplied gas.

In the above-described embodiments, by using, as coating gas, mixed gas of Si element-containing gas and H₂, an Si thin film made of a material, for example, such as poly crystalline Si (Poly-Si) is grown on the surface of the quartz member (the inner wall of the outer tube 203 or the surface of the boat 217) installed in the process chamber 201, but the present invention is not limited thereto. In addition, the present invention is not limited to the case where the coating gas supply pipe 232b is divided into two parts as in the above-described embodiment, and thus, it may be unnecessary that the coating gas supply pipe 232b is divided according to the types of supplied gas, or the coating gas supply pipe 232b may be divided into three or more parts.

In the above-described embodiments, the substrate processing apparatus 100 is configured as a vertical CVD apparatus, but the present invention is not limited thereto. For example, the present invention is very suitably applicable to a substrate processing apparatus, which have a process chamber configured to process a substrate such as a wafer under a depressurized condition, such as a horizontal CVD apparatus and a single wafer CVD apparatus.

The substrate processing apparatus according to the present invention can suppress the formation of an Si thin film on the inner wall of the film-forming gas supply nozzle.

While the embodiments of the present invention have been particularly described, various changes in form and details may be made without departing from the spirit and scope of the present invention.

### Preferred Embodiments of the Present Invention

The present invention also includes the following embodiments.

(Supplementary Note 1)

According to a preferred embodiment of the present invention, there is provided a substrate processing apparatus comprising: a process chamber configured to process a substrate; a heating member configured to heat the substrate; a coating gas supply member including a coating gas supply nozzle configured to supply coating gas into the process chamber; a film-forming gas supply member including a film-forming gas supply nozzle configured to supply film-forming gas into the process chamber; and a control unit configured to control the heating member, the coating gas supply member, and the film-forming gas supply member, wherein the control unit executes a control such that the coating gas supply nozzle supplies the coating gas to coat a quartz member in the process chamber and the film-forming gas supply nozzle supplies the film-forming gas to form an epitaxial film on the substrate.

(Supplementary Note 2)

Preferably, the control unit may supply purge gas into the film-forming gas supply nozzle to coat the quartz member in the process chamber.

(Supplementary Note 3)

Preferably, a diameter of the coating gas supply nozzle may be greater than a diameter of the film-forming gas supply nozzle.

(Supplementary Note 4)

According to another preferred embodiment of the present invention, there is provided a semiconductor device manufacturing method comprising: a process of holding a plurality of substrates in a state where the substrates are spaced a predetermined distance from each other in a stacked shape, to load the substrates into a process chamber; a process of supplying coating gas by a coating gas supply nozzle installed in the process chamber, to coat a quartz member in the process chamber; a process of supplying film-forming gas by a film-forming gas supply nozzle installed in the process chamber, to form an epitaxial film; and a process of unloading the substrates out of the process chamber.

(Supplementary Note 5)

According to another preferred embodiment of the present invention, there is provided a substrate processing apparatus comprising: a process chamber configured to process a substrate; a heating member configured to heat the substrate; a coating gas supply member including a coating gas supply nozzle configured to supply coating gas into the process chamber; a film-forming gas supply member including a film-forming gas supply nozzle configured to supply film-forming gas into the process chamber; and a control unit configured to control the heating member, the coating gas supply member, and the film-forming gas supply member, wherein the control unit executes a control to perform a process of supplying the coating gas by the coating gas supply nozzle to coat a quartz member in the process chamber and a process of supplying the film-forming gas by the film-forming gas supply nozzle to form a thin film on the substrate.

(Supplementary Note 6)

Preferably, in the process of coating the quartz member in the process chamber, purge gas may be supplied into the film-forming gas supply nozzle.

(Supplementary Note 7)

Preferably, the coating gas may be Si element-containing gas.

(Supplementary Note 8)

According to another preferred embodiment of the present invention, there is provided a semiconductor device manufacturing method comprising: a process of holding a plurality of substrates in a state where the substrates are spaced a predetermined distance from each other in a stacked shape, to load the substrates into a process chamber; a process of supplying coating gas by a coating gas supply nozzle installed in the process chamber, to coat a quartz member in the process chamber; a process of supplying film-forming gas by a film-forming gas supply nozzle installed in the process chamber, to form a thin film; and a process of unloading the substrates out of the process chamber.

What is claimed is:

1. A substrate processing apparatus comprising:
a process chamber configured to process a substrate;
a heating member configured to heat the substrate;
a coating gas supply member including a coating gas supply nozzle configured to supply coating gas into the process chamber;
a film-forming gas supply member including a film-forming gas supply nozzle configured to supply film-forming gas into the process chamber; and
a control unit configured to control the heating member, the coating gas supply member, and the film-forming gas supply member,
wherein the control unit executes a control such that the coating gas supply nozzle supplies the coating gas to coat a quartz member in the process chamber and the film-forming gas supply nozzle supplies the film-forming gas to form an epitaxial film on the substrate.

2. The substrate processing apparatus of claim 1, wherein the control unit supplies purge gas into the film-forming gas supply nozzle to coat the quartz member in the process chamber.
